(19) United States
(12) Patent Application Publication
(10) Pub. No.: US 2024/0103336 A1
(43) Pub. Date: Mar. 28, 2024

(54) LASER PROCESSING DEVICE, LASER PROCESSING METHOD, AND ELECTRONIC DEVICE MANUFACTURING METHOD

(71) Applicant: Gigaphoton Inc., Tochigi (JP)

(72) Inventor: Yasufumi KAWASUJI, Oyama-shi (JP)

(73) Assignee: Gigaphoton Inc., Tochigi (JP)

(21) Appl. No.: 18/533,238

(22) Filed: Dec. 8, 2023

Related U.S. Application Data
(63) Continuation of application No. PCT/JP2021/025819, filed on Jul. 8, 2021.

(51) Int. Cl. G02F 1/33; H01L 21/48; H01L 23/00

(52) U.S. Cl. CPC G02F 1/33; H01L 21/486; H01L 24/81; G02F 2201/305; H01L 2224/81

(57) ABSTRACT

A laser processing device includes a diffractive optical element dividing laser light into a plurality of beams of laser light and output the beams of laser light; a first acousto-optic element on which the beams of laser light from the diffractive optical element are incident, and which shifts, in accordance with a frequency of a voltage applied thereto, an optical path of the beams of laser light output therefrom along a first direction perpendicular to an irradiation direction of the beams of laser light; a first voltage application circuit applying a voltage of a desired frequency to the first acousto-optic element; a light concentrating optical system concentrating the beams of laser light output from the first acousto-optic element and radiate the beams of laser light to a workpiece; and a processor controlling the first voltage application circuit to adjust the frequency of the voltage applied to the first acousto-optic element.

### CROSS-REFERENCE TO RELATED APPLICATIONS

The present application claims the benefit of International Application No. PCT/JP2021/025819, filed on Jul. 8, 2021, the entire contents of which are hereby incorporated by reference.

### BACKGROUND

### 1. Technical Field

The present disclosure relates to a laser processing device, a laser processing method, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248.0 nm and an ArF excimer laser device for outputting laser light having a wavelength of about 193.4 nm are used.

The KrF excimer laser device and the ArF excimer laser device each have a large spectral line width of about 350 pm to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### PATENT DOCUMENTS

### List of Documents

Patent Document 1: International Publication No. WO2005/084873

### SUMMARY

A laser processing device according to an aspect of the present disclosure is configured to form a hole at each irradiation position of a plurality of beams of laser light radiated to a workpiece. Here, the laser processing device includes a diffractive optical element configured to divide laser light incident thereon into the plurality of beams of laser light and output the plurality of beams of laser light; a first acousto-optic element on which the plurality of beams of laser light from the diffractive optical element are incident, the first acousto-optic element being configured to shift, in accordance with a frequency of a voltage applied thereto, an optical path of the plurality of beams of laser light output therefrom along a first direction perpendicular to an irradiation direction of the plurality of beams of laser light; a first voltage application circuit configured to apply a voltage of a desired frequency to the first acousto-optic element; a light concentrating optical system configured to concentrate the plurality of beams of laser light output from the first acousto-optic element and radiate the plurality of beams of laser light to the workpiece; and a processor configured to control the first voltage application circuit to adjust the frequency of the voltage applied to the first acousto-optic element.

A laser processing method according to an aspect of the present disclosure is for forming a hole at each irradiation position of a plurality of beams of laser light radiated to a workpiece. Here, the laser processing method includes a diffracting step for causing laser light to be incident on a diffractive optical element and to be output as being divided into the plurality of beams of laser light; a first optical path shifting step for causing the plurality of beams of laser light from the diffractive optical element to be incident on the first acousto-optic element and applying a voltage of a desired frequency to the first acousto-optic element to shift, in accordance with the frequency of the voltage applied thereto, an optical path of the plurality of beams of laser light output from the first acousto-optic element along a first direction perpendicular to an irradiation direction of the plurality of beams of laser light; a light concentrating step for concentrating the plurality of beams of laser light output from the first acousto-optic element; and an irradiating step for irradiating the workpiece with the concentrated plurality of beams of laser light.

An electronic device manufacturing method according to an aspect of the present disclosure includes a first coupling step for coupling an interposer and an integrated circuit chip to provide electrical connection therebetween, and a second coupling step for coupling the interposer and a circuit substrate to provide electrical connection therebetween. Here, the interposer includes an insulating substrate in which a plurality of through holes are formed and conductors arranged in the plurality of through holes, and the plurality of through holes are formed by a laser processing method for forming holes at irradiation positions of a plurality of beams of laser light radiated to the insulating substrate. Here, the laser processing method includes a diffracting step for causing laser light to be incident on a diffractive optical element and to be output as being divided into the plurality of beams of laser light; a first optical path shifting step for causing the plurality of beams of laser light from the diffractive optical element to be incident on the first acousto-optic element and applying a voltage of a desired frequency to the first acousto-optic element to shift, in accordance with the frequency of the voltage applied thereto, an optical path of the plurality of beams of laser light output from the first acousto-optic element along a first direction perpendicular to an irradiation direction of the plurality of beams of laser light; a light concentrating step for concentrating the plurality of beams of laser light output from the first acousto-optic element; and an irradiating step for irradiating the substrate with the concentrated plurality of beams of laser light.

### BRIEF DESCRIPTION OF THE DRAWINGS

Embodiments of the present disclosure will be described below merely as examples with reference to the accompanying drawings.

FIG. 1 is a schematic diagram showing a schematic configuration example of an electronic device.

FIG. 2 is a flowchart showing a manufacturing method of an electronic device.

FIG. 3 is a schematic diagram showing a schematic configuration example of a laser processing device of a comparative example.

FIG. 4 is a schematic diagram showing a schematic configuration example of the laser processing device of a first embodiment.

FIG. 5 is a diagram showing an example of a state in which a plurality of beams of laser light are incident on an aperture.

FIG. 6 is a diagram showing another example of a state in which a plurality of beams of the laser light are incident on the aperture.

FIG. 7 is a flowchart showing steps of a laser processing method in the first embodiment.

FIG. 8 is a schematic diagram showing a schematic configuration example of the laser processing device of a second embodiment.

FIG. 9 is a diagram showing a state of laser processing in a third embodiment.

FIG. 10 is a diagram showing a state of laser processing after the state shown in FIG. 9.

### DESCRIPTION OF EMBODIMENTS

1. Description of electronic device manufacturing method
2. Description of laser processing system and laser processing method of comparative example
   2.1 Configuration
   2.2 Operation
   2.3 Problem
3. Description of laser processing system and laser processing method of first embodiment
   3.1 Configuration
   3.2 Operation
   3.3 Effect
4. Description of laser processing system and laser processing method of second embodiment
   4.1 Configuration
   4.2 Operation
   4.3 Effect
5. Description of laser processing system and laser processing method of third embodiment
   5.1 Operation
   5.2 Effect

Hereinafter, embodiments of the present disclosure will be described in detail with reference to the drawings.

The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Electronic Device Manufacturing Method

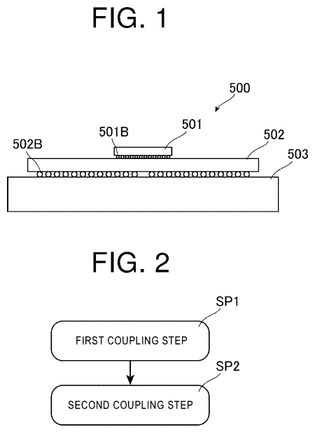

FIG. 1 is a schematic diagram showing a schematic configuration example of an electronic device 500. The electronic device 500 shown in FIG. 1 includes an integrated circuit chip 501, an interposer 502, and a circuit substrate 503. The integrated circuit chip 501 is a chip-shaped integrated circuit substrate in which an integrated circuit is formed on, for example, a silicon substrate. The integrated circuit chip 501 is provided with a plurality of bumps 501B electrically connected to the integrated circuit. The interposer 502 includes an insulating substrate in which a plurality of through holes are formed, and a conductor that electrically connects the front and back of the substrate is provided in each through hole. A plurality of lands connected to the bumps 501B provided on the integrated circuit chip 501 are formed on one surface of the interposer 502, and each land is electrically connected to one of the conductors in the through holes. A plurality of bumps 502B are provided on the other surface of the interposer 502, and each bump 502B is electrically connected to one of the conductors in the through holes. A plurality of lands connected to the respective bumps 502B are formed on one surface of the circuit substrate 503. The circuit substrate 503 includes a plurality of terminals electrically connected to the lands.

FIG. 2 is a flowchart showing a manufacturing method of the electronic device 500. As shown in FIG. 2, the manufacturing method of the electronic device 500 in the present description includes a first coupling step SP1 and a second coupling step SP2. In the first coupling step SP1, the integrated circuit chip 501 and the interposer 502 are coupled. Specifically, each bump 501B of the integrated circuit chip 501 is arranged on a corresponding land of the interposer 502 to electrically connect the bumps 501B and the lands. Thus, the integrated circuit chip 501 and the interposer 502 are electrically connected to each other. In the second coupling step SP2, the interposer 502 and the circuit substrate 503 are coupled. Specifically, each bump 502B of the interposer 502 is arranged on a corresponding of the circuit substrate 503 to electrically connect the bumps 502B and the lands. Thus, the integrated circuit chip 501 is electrically connected to the circuit substrate 503 via the interposer 502. Through the above steps, the electronic device 500 is manufactured.

### 2. Description of Laser Processing System and Laser Processing Method of Comparative Example

### 2.1 Configuration

A laser processing system and a laser processing method of a comparative example will be described. The comparative example of the present disclosure is an example recognized by the applicant as known only by the applicant, and is not a publicly known example admitted by the applicant.

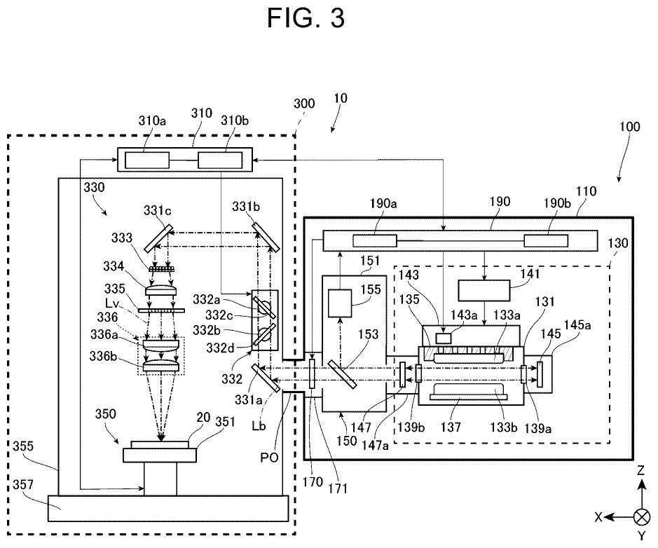

FIG. 3 is a schematic diagram showing a schematic configuration example of the entire laser processing system 10 of the present example. The laser processing system 10 of the present example includes a gas laser device 100, a laser processing device 300, and an optical path pipe PO that connects the gas laser device 100 and the laser processing device 300 as a main configuration. In the following, a direction parallel to the optical axis direction of laser light incident on a workpiece 20 is described as a Z direction, a direction perpendicular to the Z direction is described as an X direction, and a direction perpendicular to the X direction and the Z direction is described as a Y direction. The Z direction is also a height direction of the workpiece 20.

The gas laser device 100 of the present example is an ArF excimer laser device using a mixed gas including argon (Ar), fluorine (F₂), and neon (Ne). The gas laser device 100 outputs laser light having a center wavelength of about 193.4 nm. Here, the gas laser device 100 may be a gas laser device other than the ArF excimer laser device, and may be, for example, a KrF excimer laser device using a mixed gas including krypton (Kr), F₂, and Ne. In this case, the gas laser device 100 outputs laser light having a center wavelength of about 248.0 nm. The mixed gas containing Ar, F₂, and Ne which is a laser medium and the mixed gas containing Kr, F₂, and Ne which is a laser medium may be referred to as a laser gas.

The gas laser device 100 includes a housing 110, a laser oscillator 130 arranged at the internal space of the housing 110, a monitor module 150, a shutter 170, and a laser processor 190 as a main configuration.

The laser oscillator 130 includes a laser chamber 131, a charger 141, a pulse power module 143, a rear mirror 145, and an output coupling mirror 147. In FIG. 3, the internal configuration of the laser chamber 131 is shown as viewed from a direction substantially perpendicular to the travel direction of the laser light.

The laser chamber 131 includes the internal space in which light is generated by excitation of a laser medium in the laser gas. The laser gas is supplied from a laser gas supply source (not shown) to the internal space of the laser chamber 131 via a pipe (not shown). The light generated by excitation of the laser medium travels to windows 139a, 139b which will be described later.

At the internal space of the laser chamber 131, a pair of electrodes 133a, 133b are arranged to face each other and have a longitudinal direction along the travel direction of the light. The electrodes 133a, 133b are discharge electrodes for exciting the laser medium by glow discharge. In the present example, the electrode 133a is the cathode and the electrode 133b is the anode.

The electrode 133a is supported by an electrically insulating portion 135. The electrically insulating portion 135 blocks an opening formed in the laser chamber 131. A conductive portion is embedded in the electrically insulating portion 135, and the conductive portion applies a high voltage supplied from the pulse power module 143 to the electrode 133a. The electrode 133b is supported by a return plate 137. The return plate 137 is connected to an inner surface of the laser chamber 131 by wiring (not shown).

The charger 141 is a DC power source device that charges a charging capacitor (not shown) in the pulse power module 143 with a predetermined voltage. The pulse power module 143 includes a switch 143a controlled by the laser processor 190. When the switch 143a is turned ON from OFF, the pulse power module 143 generates a pulse high voltage from the electric energy held in the charger 141 and applies the high voltage between the electrode 133a and the electrode 133b.

When the high voltage is applied between the electrode 133a and the electrode 133b, discharge occurs between the electrode 133a and the electrode 133b. The energy of the discharge excites the laser medium in the laser chamber 131. Light is emitted when the excited laser medium shifts to the ground state.

The laser chamber 131 is provided with the windows 139a, 139b. The window 139a is located on one end side of the laser chamber 131 in the travel direction of the laser light, the window 139b is located on the other end side in the travel direction, and the windows 139a, 139b sandwich a space between the electrode 133a and the electrode 133b. The laser light oscillated as described later is output to the outside of the laser chamber 131 through the windows 139a, 139b. Since a pulse high voltage is applied between the electrode 133a and the electrode 133b by the pulse power module 143 as described above, the laser light is pulse laser light.

The rear mirror 145 is arranged at the internal space of a housing 145a connected to the one end side of the laser chamber 131, and reflects the laser light output from the window 139a to return the laser light to the internal space of the laser chamber 131. The output coupling mirror 147 is arranged at the internal space of the optical path pipe 147a connected to the other end side of the laser chamber 131, transmits a part of the laser light output from the window 139b, and reflects the other part to return to the internal space of the laser chamber 131. Thus, the rear mirror 145 and the output coupling mirror 147 configure a Fabry-Perot laser resonator, and the laser chamber 131 is arranged on the optical path of the laser resonator.

The monitor module 150 is arranged on the optical path of the laser light output from the output coupling mirror 147. The monitor module 150 includes a housing 151, a beam splitter 153, and an optical sensor 155. An opening is formed in the housing 151, and the internal space of the housing 151 communicates with the internal space of the optical path pipe 147a via the opening. The beam splitter 153 and the optical sensor 155 are arranged at the internal space of the housing 151.

The beam splitter 153 transmits the laser light output from the output coupling mirror 147 toward the shutter 170 at a high transmittance, and reflects a part of the laser light toward a light receiving surface of the optical sensor 155. The optical sensor 155 measures an energy E of the laser light incident on the light receiving surface. The optical sensor 155 is electrically connected to the laser processor 190, and outputs a signal indicating the measured energy E to the laser processor 190.

The laser processor 190 of the present disclosure is a processing device including a storage device 190a in which a control program is stored and a central processing unit (CPU) that executes the control program. The laser processor 190 is specifically configured or programmed to perform various processes included in the present disclosure. The laser processor 190 controls the entire gas laser device 100.

The laser processor 190 receives the signal indicating the energy E from the optical sensor 155 of the monitor module 150. The laser processor 190 transmits and receives various signals to and from a laser processing processor 310 of the laser processing device 300. For example, the laser processor 190 receives a later-described light emission trigger Tr and a later described target energy Et from the laser processing processor 310. The laser processor 190 controls the charge voltage of the charger 141 based on the energy E and the target energy Et received from the optical sensor 155 and the laser processing processor 310. By controlling the charge voltage of the charger 141, the energy of the laser light is controlled. Further, the laser processor 190 transmits a command signal of ON or OFF of the switch 143a to the pulse power module 143. Further, the laser processor 190 controls opening and closing of the shutter 170.

The shutter 170 is arranged on the optical path of the laser light transmitted through the beam splitter 153 at the internal space of the optical path pipe 171 connected to the housing 151 of the monitor module 150. The optical path pipe 171 is connected to a side of the housing 151 opposite to a side to which the optical path pipe 147a is connected, and the internal space of the optical path pipe 171 communicates with the internal space of the housing 151 via an opening formed in the housing 151. Further, the optical path pipe 171 communicates with the optical path pipe PO via an opening formed in the housing 110.

The shutter 170 is electrically connected to the laser processor 190. The laser processor 190 closes the shutter 170 until a difference ΔE between the energy E received from the monitor module 150 and the target energy Et received from the laser processing processor 310 falls within an allowable range. Further, the laser processor 190 opens the shutter 170 when receiving a signal indicating the light emission trigger Tr from the laser processing processor 310. Here, when the difference ΔE falls within the allowable range, the laser processor 190 transmits, to the laser processing processor 310, a reception preparation completion signal indicating that reception preparation of the light emission trigger Tr is completed. The light emission trigger Tr is defined by a predetermined repetition frequency f and a predetermined number of pulses P of the laser light, is a timing signal for the laser processing processor 310 to cause the laser oscillator 130 to perform laser oscillation, and is an external trigger. The repetition frequency f of the laser light is, for example, 1 kHz or more and 10 kHz or less.

The internal spaces of the optical path pipe 171 and the optical path pipe 147a and the internal spaces of the housing 151 and the housing 145a are filled with a purge gas. The purge gas includes an inert gas such as high purity nitrogen. The purge gas is supplied from a purge gas supply source (not shown) to the internal spaces of the optical path pipe 171 and the optical path pipe 147a and the internal spaces of the housing 151 and the housing 145a through pipes (not shown).

Here, an exhaust device (not shown) for exhausting the laser gas exhausted from the internal space of the laser chamber 131 is arranged at the internal space of the housing 110 of the gas laser device 100. The exhaust device performs a process such as removing an F₂ gas from the gas exhausted from the internal space of the laser chamber 131 using a halogen filter, and discharges the gas to the housing 110 of the gas laser device 100.

While the shutter 170 is open, the laser light passes through the shutter 170, and laser light Lb is output from the optical path pipe 171 of the gas laser device 100.

The laser processing device 300 includes the laser processing processor 310, an optical system 330, a stage 350, a housing 355, and a frame 357 as a main configuration. The optical system 330 and the stage 350 are arranged at the internal space of the housing 355. The housing 355 is fixed to the frame 357. The optical path pipe PO is connected to the housing 355, and the internal space of the housing 355 communicates with the internal space of the optical path pipe PO via an opening formed in the housing 355.

The laser processing processor 310 is a processing device including a storage device 310a in which a control program is stored and a CPU 310b that executes the control program. The laser processing processor 310 is specifically configured or programmed to perform various processes included in the present disclosure. The laser processing processor 310 controls the entire laser processing device 300.

The optical system 330 includes high reflection mirrors 331a, 331b, 331c, an attenuator 332, a fly-eye lens 333, a condenser lens 334, a mask 335, and a projection optical system 336. Each configuration of the optical system 330 is fixed to a holder (not shown), and is arranged at a predetermined position in the housing 355.

The high reflection mirrors 331a, 331b, 331c are each formed by coating a reflection film that highly reflects the laser light Lb on the surface of a transparent substrate formed of, for example, synthetic quartz or calcium fluoride. The high reflection mirror 331a reflects, toward the attenuator 332, the laser light Lb incident from the gas laser device 100. The high reflection mirror 331b reflects, toward the high reflection mirror 331c, the laser light Lb from the attenuator 332. The high reflection mirror 331c reflects, toward the fly-eye lens 333, the laser light Lb from the high reflection mirror 331b.

The attenuator 332 is arranged on the optical path between the high reflection mirror 331a and the high reflection mirror 331b. The attenuator 332 includes, for example, rotation stages 332a, 332b and partial reflection mirrors 332c, 332d fixed to the rotation stages 332a, 332b. Each rotation stage 332a, 332b is electrically connected to the laser processing processor 310 and rotates about the Y axis by a control signal from the laser processing processor 310. When the rotation stages 332a, 332b rotate, the partial reflection mirrors 332c, 332d also rotate. The partial reflection mirrors 332c, 332d are optical elements in which the transmittances of the partial reflection mirrors 332c, 332d vary depending on the incident angles of the laser light Lb on the partial reflection mirrors 332c, 332d. The rotation angles of the partial reflection mirrors 332c, 332d about the Y axis are adjusted by the rotation of the rotation stages 332a, 332b so that the incident angles of the laser light Lb coincide with each other and the transmittances of the partial reflection mirrors 332c, 332d become desired transmittances. Accordingly, the laser light Lb from the high reflection mirror 331a is attenuated to a desired energy and passes through the attenuator 332.

The fly-eye lens 333 is a lens in which a plurality of lenses are arranged in parallel in a honeycomb shape, for example, and is also called an integrator lens. The fly-eye lens 333 is arranged such that the focal plane on the output side of the fly-eye lens 333 coincides with the focal plane on the incident side of the condenser lens 334, and outputs light such that the energy density of the laser light Lb incident on the condenser lens 334 becomes uniform.

The condenser lens 334 is a lens that concentrates the laser light Lb output from the fly-eye lens 333, and is arranged such that the focal plane of the condenser lens 334 on the output side is on the mask 335.

The mask 335 is, for example, a plate-shaped member in which a plurality of transmission holes through which a part of the laser light Lb is transmitted is formed and which blocks the other part of the laser light Lb. In the present example, the transmission holes are a plurality of circular holes. As the laser light Lb is transmitted through the plurality of transmission holes, the laser light Lb is divided into a plurality of beams of laser light Lv, and a transfer pattern is formed on a processing portion. When the transfer pattern is transferred to the workpiece 20, a through hole corresponding to the transfer pattern is formed in the workpiece 20.

The projection optical system 336 includes, for example, a collimator lens 336a and a light concentrating lens 336b. The collimator lens 336a outputs the plurality of beams of the laser light Lv from the mask 335 as collimated light. The light concentrating lens 336b concentrates the plurality of beams of the laser light Lv from the collimator lens 336a on the workpiece 20 so that the transfer pattern forms an image at an imaging position located at a predetermined depth ΔZsf from the front surface of the workpiece 20. The magnification of the projection optical system 336 is, for example, 1/10 to ⅕.

The stage 350 is arranged on the bottom surface of the housing 355 and includes a table 351. Further, the stage 350 can move the table 351 in the X direction, the Y direction, and the Z direction by a control signal from the laser processing processor 310, and can adjust the position of the table 351 by this movement.

The table 351 supports the workpiece 20. The main surface of the table 351 is substantially perpendicular to the Z axis and substantially along the XY plane. Therefore, the front surface and the back surface of the workpiece 20 are substantially perpendicular to the Z axis and substantially along the XY plane. With the above configuration, the stage 350 can adjust the position of the workpiece 20 by moving the workpiece 20 via the table 351 so that a desired position of the workpiece 20 is irradiated with the plurality of beams of the laser light Lv output from the optical system 330.

The workpiece 20 is an object on which laser processing is performed by radiating the plurality of beams of the laser light Lv. Examples of the workpiece 20 include an insulating substrate to be the interposer 502 described with reference to FIG. 1. Examples of the material of the insulating substrate include an inorganic material such as silicon and glass, and a composite material of an inorganic material and an organic material such as a resin such as polyimide, and glass epoxy and the like.

An inert gas constantly flows at the internal space of the housing 355 during operation of the laser processing system 10. The inert gas is, for example, nitrogen (N₂). The housing 355 is provided with a suction port (not shown) for sucking the inert gas into the housing 355, and an exhaust port (not shown) for exhausting the inert gas from the housing 355 to the outside. A suction pipe (not shown) and an exhaust pipe (not shown) are connected to the suction port and the exhaust port, respectively. A gas supply source (not shown) for supplying the inert gas is connected to the suction port. The inert gas supplied from the suction port also flows to the optical path pipe PO that communicates with the housing 355.

### 2.2 Operation

Next, operation of the laser processing system and the laser processing method of the comparative example will be described.

Before the gas laser device 100 outputs the laser light Lb, a purge gas is filled from a purge gas supply source (not shown) into the internal spaces of the optical path pipes 147a, 171, PO and the internal spaces of the housings 145a, 151 in the gas laser device 100. Further, a laser gas is supplied to the internal space of the laser chamber 131 from the laser gas supply source (not shown). In the laser processing device 300, an inert gas such as a nitrogen gas flows at the internal space of the housing 355.

In the laser processing device 300, the workpiece 20 is supported on the table 351. The laser processing processor 310 sets, to the stage 350, a coordinate X, a coordinate Y, and a coordinate Z of an irradiation position to be irradiated with a plurality of beams of the laser light Lv to form a processing portion. The irradiation position is the processing portion on the workpiece 20 on which the transfer pattern is to be formed. Accordingly, the stage 350 moves the table 351 so that the irradiation position becomes a desired position on the workpiece 20.

After the table 351 is moved, the laser processing processor 310 controls the gas laser device 100 and a transmittance Tm of the attenuator 332 of the optical system 330 so that the plurality of beams of the laser light Lv radiated to the workpiece 20 have a desired fluence Fm required for laser processing.

The laser processor 190 closes the shutter 170 and activates the charger 141. Further, the laser processor 190 turns ON the switch 143a of the pulse power module 143. Thus, the pulse power module 143 applies a pulse high voltage from the electric energy held in the charger 141 between the electrode 133a and the electrode 133b. The high voltage causes discharge between the electrode 133a and the electrode 133b, the laser medium contained in the laser gas between the electrode 133a and the electrode 133b is brought into an excited state, and light is emitted when the laser medium returns to the ground state. The light resonates between the rear mirror 145 and the output coupling mirror 147, and is amplified every time it passes through the discharge space at the internal space of the laser chamber 131, thereby causing laser oscillation. A part of the laser light is transmitted through the output coupling mirror 147 and propagates to the beam splitter 153.

A part of the laser light having traveled to the beam splitter 153 is reflected by the beam splitter 153 and is received by the optical sensor 155. The optical sensor 155 measures the energy E of the received laser light, and outputs a signal indicating the energy E to the laser processor 190. After the energy E falls within a predetermined range, the laser processor 190 transmits, to the laser processing processor 310, a reception preparation completion signal indicating that reception preparation of the light emission trigger Tr of the laser light is completed.

Thereafter, the laser processing processor 310 transmits the light emission trigger Tr to the laser processor 190. As a result, the laser processor 190 opens the shutter 170, and the laser light that has passed through the shutter 170 is output from the gas laser device 100 and enters the laser processing device 300. The laser light Lb is, for example, pulse laser light having a center wavelength of 193.4 nm.

The laser light Lb having entered the laser processing device 300 is radiated to the mask 335 via the high reflection mirror 331a, the attenuator 332, the high reflection mirrors 331b, 331c, the fly-eye lens 333, and the condenser lens 334. At this time, the laser light Lb is Kohler-illuminated on the mask 335. At the mask 335, among the laser light Lb, a part of the laser light is transmitted through the mask pattern to become the plurality of beams of the laser light Lv, and the other part of the laser light is blocked. The plurality of beams of the laser light Lv transmitted through the mask 335 are collimated by the collimator lens 336a of the projection optical system 336, and are imaged by the light concentrating lens 336b at the imaging position of the workpiece 20.

The plurality of beams of the laser light Lv are radiated to the workpiece 20 in accordance with the light emission trigger Tr defined by the repetition frequency f and the number of pulses P required for laser processing. In the vicinity of the front surface of the workpiece 20, ablation occurs due to the irradiation with the laser light Lv, and a defect occurs. Thus, the processing portion is processed and a hole is formed in the workpiece 20. In the present example, processing is performed until a plurality of through holes are formed in the workpiece 20.

In a case in which, after a processing portion is processed at a part of the workpiece 20, another processing portion is to be processed at another part of the workpiece 20, the laser processing processor 310 sets the coordinate X and the coordinate Y of a new irradiation position to the stage 350 to irradiate the other processing portion with a plurality of beams of the laser light Lv. The stage 350 moves the table 351 together with the workpiece 20 so that the newly set irradiation position is irradiated with the plurality of beams of the laser light Lv. Thereafter, laser processing is performed on the workpiece 20 at the coordinates. When another processing portion is not to be formed, laser processing is terminated. Such a procedure is repeated until laser processing for all processing portions is completed.

### 2.3 Problem

In the laser processing device 300 of the comparative example, a part of the laser light Lb is blocked by the mask 335 as described above. Therefore, utilization efficiency of the laser light Lb is low, and throughput is low.

Therefore, in the following embodiments, a laser processing device and a laser processing method capable of improving energy efficiency are exemplified.

### 3. Description of Laser Processing System and Laser Processing Method of First Embodiment

Next, the laser processing system and the laser processing method of a first embodiment will be described. Any component same as that described above is denoted by an identical reference sign, and duplicate description thereof is omitted unless specific description is needed.

### 3.1 Configuration

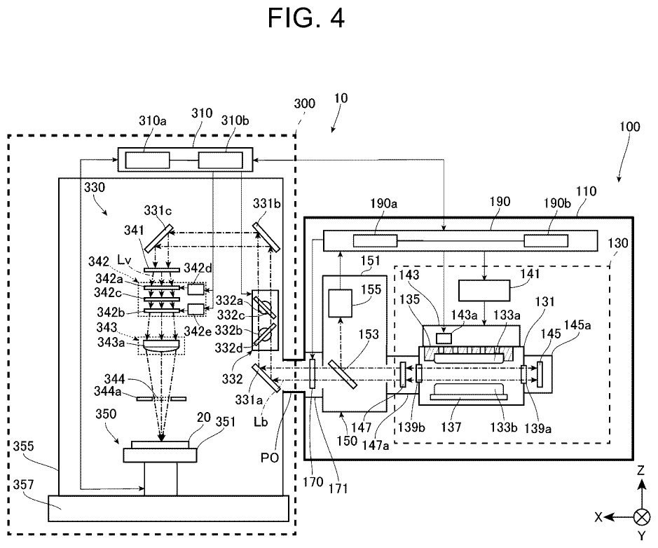

FIG. 4 is a schematic diagram showing a schematic configuration example of the entire laser processing system 10 of the present embodiment. In the laser processing system 10 of the present embodiment, the configuration of the optical system 330 is different from the configuration of the optical system 330 of the comparative example. The optical system 330 of the present embodiment includes the high reflection mirrors 331a, 331b, 331c, the attenuator 332, a diffractive optical element (DOE) 341, an acousto-optic element module 342, a light concentrating optical system 343, and an aperture 344. Each configuration of the optical system 330 is fixed to a holder (not shown), and is arranged at a predetermined position in the housing 355.

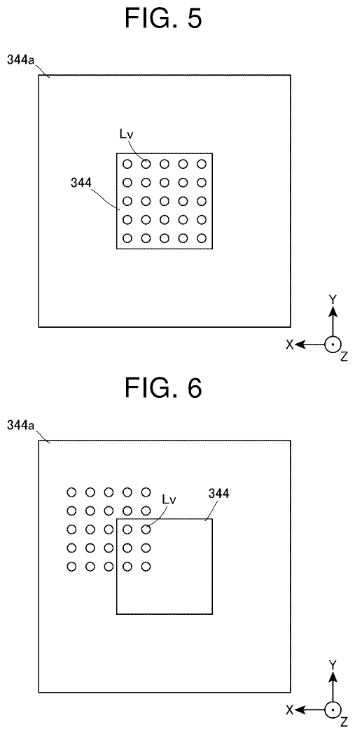

The diffractive optical element 341 diffracts the laser light Lb incident from the high reflection mirror 331c, divides the laser light Lb into a plurality of beams of the laser light Lv, and outputs the laser light Lv. FIG. 5 is a diagram showing an example of a state in which the plurality of beams of the laser light Lv are incident on the aperture 344. The pattern of the plurality of beams of the laser light Lv output from the diffractive optical element 341 is similar to the pattern of the plurality of beams of the laser light Lv shown in FIG. 5. In the example shown in FIG. 5, the diffractive optical element 341 has a square lattice matrix pattern in which the plurality of beams of the laser light Lv are arranged in plural in the X direction and in plural in the Y direction. The square lattice in this example is a 5×5 pattern. The X direction is a first direction perpendicular to the irradiation direction of the plurality of beams of the laser light Lv, and the Y direction is a second direction perpendicular to the irradiation direction of the plurality of beams of the laser light Lv and the first direction.

The acousto-optic element module 342 includes a first acousto-optic element 342a, a λ/2 wave plate 342c, a second acousto-optic element 342b, a first voltage application circuit 342d, and a second voltage application circuit 342e.

The first voltage application circuit 342d applies a voltage of a desired frequency to the first acousto-optic element 342a, and the second voltage application circuit 342e applies a voltage of a desired frequency to the second acousto-optic element 342b. The first voltage application circuit 342d and the second voltage application circuit 342e are electrically connected to the laser processing processor 310, and the magnitude of the voltages applied to the first acousto-optic element 342a and the second acousto-optic element 342b and the frequencies of the voltages can be changed by a signal from the laser processing processor 310.

The plurality of beams of the laser light Lv output from the diffractive optical element 341 are incident on the first acousto-optic element 342a. When a periodic voltage is applied to the acousto-optic element, the optical path of light output from a grating is shifted due to a periodic change in refractive index caused by a photoelastic effect. The amount of shift in the optical path varies in accordance with the frequency of the voltage applied thereto. The first acousto-optic element 342a shifts the optical path of the plurality of beams of the laser light Lv output therefrom along the first direction in accordance with the frequency of the voltage applied thereto. Further, the plurality of beams of the laser light Lv output from the first acousto-optic element 342a are incident on the second acousto-optic element 342b. The second acousto-optic element 342b shifts the optical path of the plurality of beams of the laser light Lv output therefrom along the second direction in accordance with the frequency of the voltage applied thereto. The amount of shift by which the first acousto-optic element 342a shifts the optical path of the plurality of beams of the laser light Lv along the first direction and the amount of shift by which the second acousto-optic element 342b shifts the optical path along the second direction are each, for example, between 0.01 and 1.0 degrees.

The λ/2 wave plate 342c is arranged between the first acousto-optic element 342a and the second acousto-optic element 342b. Therefore, the laser light Lv output from the first acousto-optic element 342a is incident on the second acousto-optic element 342b via the λ/2 wave plate 342c. The λ/2 wave plate 342c rotates the two polarization directions of the laser light Lv incident thereon by 90 degrees. Therefore, the relationship between the polarization direction of the linear polarization of the laser light Lv incident on the first acousto-optic element 342a and the first direction and the relationship between the polarization direction of the linear polarization of the laser light Lv incident on the second acousto-optic element 342b and the second direction can be aligned. Therefore, when the characteristics of the first acousto-optic element 342a and the characteristics of the second acousto-optic element 342b are the same and voltages of the same frequency are applied to the first acousto-optic element 342a and the second acousto-optic element 342b, the manner of shift of the plurality of beams of the laser light Lv output from the first acousto-optic element 342a in the first direction and the manner of shift of the plurality of beams of the laser light Lv output from the second acousto-optic element 342b in the second direction can be aligned.

The light concentrating optical system 343 of the present embodiment includes a light concentrating lens 343a. The light concentrating lens 343a is arranged such that the focal plane on the incident side is located substantially on the output surface of the second acousto-optic element 342b, and the focal plane on the output side is located substantially at a predetermined depth from the workpiece 20. The predetermined depth is, for example, similar to the imaging position in the comparative example.

The aperture 344 is arranged between the workpiece 20 and the light concentrating optical system 343. The aperture 344 of the present example is an opening formed in a frame member 344a, and the opening has a quadrangular shape formed of a pair of sides extending in the first direction and a pair of sides extending in the second direction. In the example shown in FIG. 5, all of the plurality of beams of the laser light Lv divided by the diffractive optical element 341 are transmitted through the aperture 344. In the present example, the plurality of beams of the laser light Lv transmitted through the aperture 344 are radiated to the workpiece 20.

FIG. 6 is a diagram showing another example of a state in which the plurality of beams of the laser light Lv are incident on the aperture 344. In the example of FIG. 6, among the plurality of beams of the laser light Lv, a part of the plurality of beams of the laser light Lv is transmitted through the aperture 344, and the other part of the laser light Lv is blocked by the frame member 344a without being transmitted through the aperture 344. In the example of FIG. 6, the plurality of beams of the laser light Lv transmitted through the acousto-optic element module 342 are shifted in the X direction and the Y direction. Specifically, as compared with the case in which the plurality of beams of the laser light Lv are transmitted through the acousto-optic element module 342 as shown in FIG. 5, the optical path of the plurality of beams of the laser light Lv transmitted through the first acousto-optic element 342a is shifted in the X direction along the first direction, and the optical path of the plurality of beams of the laser light Lv transmitted through the second acousto-optic element 342b is shifted in the Y direction along the second direction. In this case, the frequency of the voltage applied from the first voltage application circuit 342d to the first acousto-optic element 342a and the frequency of the voltage applied from the second voltage application circuit 342e to the second acousto-optic element 342b differ from respectively the frequencies of the voltages in the state of FIG. 5. The shift amount is determined by the laser processing processor 310. That is, the laser processing processor 310 controls the first voltage application circuit 342d and the second voltage application circuit 342e to adjust the frequencies of the voltages applied to the first acousto-optic element 342a and the second acousto-optic element 342b so that, among the plurality of beams of the laser light Lv transmitted through the aperture 344, the number of the beams arranged in the first direction and the number of the beams arranged in the second direction become desired numbers, respectively.

Here, the laser processing processor 310 may control the first voltage application circuit 342d and the second voltage application circuit 342e to adjust the frequencies of the voltages applied to the first acousto-optic element 342a and the second acousto-optic element 342b so that the number of beams of the laser light Lv transmitted through the aperture 344 change in accordance with the position of the workpiece 20. For example, when the processing position of the workpiece 20 is a certain position, the laser processing processor 310 controls the first voltage application circuit 342d and the second voltage application circuit 342e so that the plurality of beams of the laser light Lv are transmitted through the aperture 344 as shown in FIG. 5. When the table 351 moves and the processing position of the workpiece 20 is another certain position, the laser processing processor 310 controls the first voltage application circuit 342d and the second voltage application circuit 342e so that, among the plurality of beams of the laser light Lv, a part of the beams of the laser light Lv is transmitted through the aperture 344 and the other part of the beams of the laser light Lv is not transmitted through the aperture 344 as shown in FIG. 6. Thus, the laser processing processor 310 may control the first voltage application circuit 342d and the second voltage application circuit 342e to adjust the frequencies of the voltages applied to the first acousto-optic element 342a and the second acousto-optic element 342b so that the number of beams of the laser light Lv transmitted through the aperture 344 change in accordance with the position of the workpiece 20.

### 3.2 Operation

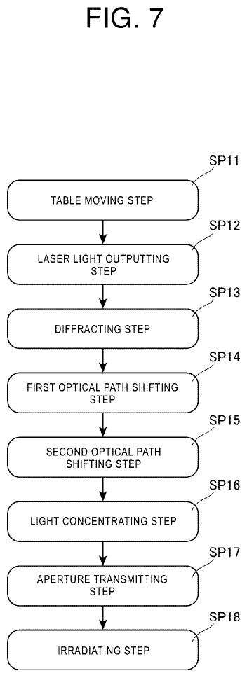

Next, operation of the laser processing system 10 and the laser processing method of the present embodiment will be described. FIG. 7 is a flowchart showing steps of the laser processing method in the present embodiment. As shown in FIG. 7, the laser processing method of the present embodiment includes a table moving step SP11, a laser light outputting step SP12, a diffracting step SP13, a first optical path shifting step SP14, a second optical path shifting step SP15, a light concentrating step SP16, an aperture transmitting step SP17, and an irradiating step SP18.

### (Table Moving Step SP11)

The present step is a step of moving the table 351 of the stage 350 to radiate a plurality of beams of the laser light Lv to a desired position on the workpiece 20. In the present step, the laser processing processor 310 sets the coordinate X, the coordinate Y, and the coordinate Z of the irradiation position to be irradiated with the plurality of beams of the laser light Lv to the stage 350 so that a desired position on the workpiece 20 becomes the processing portion. When the setting is performed, the stage 350 moves the table 351 on which the workpiece 20 is placed so that the set irradiation position is irradiated with the plurality of beams of the laser light Lv. When the movement of the table 351 is completed, the stage 350 transmits a signal indicating the completion to the laser processing processor 310. Thus, the table moving step SP11 is completed.

### (Laser Light Outputting Step SP12)

When the laser processing processor 310 receives the signal indicating that the movement of the table 351 is completed, the laser processing processor 310 controls the gas laser device 100 in a similar manner as described in the comparative example. At this time, the laser processing processor 310 causes, among the plurality of beams of the laser light Lv, the number of the beams of the laser light Lv transmitted through the aperture 344 arranged in the first direction which is the X direction and the number thereof arranged in the second direction which is the Y direction to be desired numbers in accordance with the X coordinate, the Y coordinate, and the Z coordinate of the irradiation position on the workpiece 20 to be irradiated with the plurality of beams of the laser light Lv. Specifically, the laser processing processor 310 controls the first voltage application circuit 342d and the second voltage application circuit 342e to adjust the frequencies of the voltages applied to the first acousto-optic element 342a and the second acousto-optic element 342b, respectively. Therefore, when the laser light Lb is output from the gas laser device 100, voltages of desired frequencies are applied to the first acousto-optic element 342a and the second acousto-optic element 342b. Further, the laser processing processor 310 adjusts the attenuator 332 in a similar manner as in the comparative example so that the transmittance of the attenuator 332 becomes the desired transmittance. After the laser light Lb is thus ready to be output from the gas laser device 100, the gas laser device 100 outputs the laser light Lb. The laser light Lb is pulse laser light.

### (Diffracting Step SP13)

The present step is a step of causing the laser light Lb to be incident on the diffractive optical element 341, and to be output as being divided into the plurality of beams of the laser light Lv. The laser light Lb output from the gas laser device 100 in the laser light outputting step SP12 propagates in the order of the high reflection mirror 331a, the attenuator 332, and the high reflection mirrors 331b, 331c. The laser light Lb reflected by the high reflection mirror 331c is incident on the diffractive optical element 341. The laser light Lb incident on the diffractive optical element 341 is divided into the plurality of beams of the laser light Lv in accordance with the diffraction pattern of the diffractive optical element 341, and is output from the diffractive optical element 341. At this time, the pattern of the plurality of beams of the laser light Lv output from the diffractive optical element 341 is the matrix pattern shown in FIG. 5.

### (First Optical Path Shifting Step SP14)

The present step is a step of causing the plurality of beams of the laser light Lv from the diffractive optical element 341 to be incident on the first acousto-optic element 342a, and changing the optical path of the plurality of beams of the laser light Lv output from the first acousto-optic element 342a along the first direction. When the laser light Lb is output from the gas laser device 100 as described above, a voltage of a desired frequency is applied to the first acousto-optic element 342a. Therefore, the optical path of the plurality of beams of the laser light Lv incident on the first acousto-optic element 342a shifts along the first direction in accordance with the frequency of the voltage, and the laser light Lv is output from the first acousto-optic element 342a.

### (Second Optical Path Shifting Step SP15)

The present step is a step of causing the plurality of beams of the laser light Lv from the first acousto-optic element 342a to be incident on the second acousto-optic element 342b, and changing the optical path of the plurality of beams of the laser light Lv output from the second acousto-optic element 342b along the second direction. Here, before the present step, the plurality of beams of the laser light Lv output from the first acousto-optic element 342a are transmitted through the λ/2 wave plate 342c, and the polarization direction thereof is rotated by 90 degrees. Therefore, linear polarization, along the first direction, of the plurality of beams of the laser light Lv output from the first acousto-optic element 342a becomes linear polarization along the second direction when the laser light Lv is incident on the second acousto-optic element 342b. When the laser light Lb is output from the gas laser device 100 as described above, a voltage of a desired frequency is applied to the second acousto-optic element 342b. Therefore, the optical path of the plurality of beams of the laser light Lv incident on the second acousto-optic element 342b shifts along the second direction in accordance with the frequency of the voltage, and the laser light Lv is output from the second acousto-optic element 342b.

Here, as shown in FIG. 5, even when all of the plurality of beams of the laser light Lv are transmitted through the aperture 344, it is preferable that voltages of desired frequencies are applied to the first voltage application circuit 342d and the second voltage application circuit 342e. Therefore, even in this case, the optical path is shifted at the first acousto-optic element 342a and the second acousto-optic element 342b. By applying the voltage of the desired frequency as described above and finely adjusting the frequency of the voltage, it is easy to finely adjust the irradiation position of the plurality of beams of the laser light Lv that are transmitted through the aperture 344 and radiated to the workpiece 20. That is, it is preferable that, when the plurality of beams of the laser light Lv is radiated to the workpiece 20, voltages of desired frequencies are always applied to the first voltage application circuit 342d and the second voltage application circuit 342e and the optical path is shifted at the first acousto-optic element 342a and the second acousto-optic element 342b.

### (Light Concentrating Step SP16)

The present step is a step of concentrating the plurality of beams of the laser light Lv. The plurality of beams of the laser light Lv output from the first acousto-optic element 342a are incident on the light concentrating optical system 343 via the λ/2 wave plate 342c and the second acousto-optic element 342b. Since the light concentrating optical system 343 of the present embodiment includes the light concentrating lens 343a, the plurality of beams of the laser light Lv from the second acousto-optic element 342b is transmitted through the light concentrating lens 343a. The plurality of beams of the laser light Lv transmitted through the light concentrating lens 343a are concentrated in accordance with the numerical aperture of the light concentrating lens 343a.

### (Aperture Transmitting Step SP17)

The present step is a step of transmitting the plurality of beams of the laser light Lv concentrated in the light concentrating step SP16 through the aperture 344. When the first voltage application circuit 342d and the second voltage application circuit 342e are controlled so that all of the beams of the laser light Lv are transmitted through the aperture 344, as shown in FIG. 5, all of the beams of the laser light Lv are incident on the aperture 344 and are transmitted through the aperture 344. On the other hand, when a part of the beams of the laser light Lv is transmitted through the aperture 344 and the other part of the beams of the laser light Lv is not transmitted through the aperture 344, for example, as shown in FIG. 6, only a part of the beams of the laser light Lv is incident on the aperture 344 and is transmitted through the aperture 344, and the other part of the beams of the laser light Lv is blocked by the frame member 344a. That is, in the first optical path shifting step SP14 and the second optical path shifting step SP15, the laser processing processor 310 adjusts the frequencies of the voltages applied to the first acousto-optic element 342a and the second acousto-optic element 342b so that, among the plurality of beams of the laser light Lv transmitted through the aperture 344, the number of beams of the laser light Lv transmitted through the aperture 344 arranged in the first direction and the number thereof arranged in the second direction become desired numbers, respectively.

### (Irradiating Step SP18)

The present step is a step of irradiating the workpiece 20 with the plurality of beams of the laser light Lv concentrated in the light concentrating step SP16. In the plurality of beams of the laser light Lv concentrated in the light concentrating step SP16, the spot diameter of each of the beams of the laser light Lv decreases, and the distance between the beams of the laser light Lv decreases. The plurality of beams of the laser light Lv concentrated in this manner are radiated to the workpiece 20. Since the laser light Lb is pulse laser light, the radiated laser light Lv is pulse laser light. At each irradiation position, the workpiece 20 is ablated to form a hole. In the case that the workpiece 20 is a substrate to be the interposer 502, the present step is performed until the hole becomes a through hole, and thereafter, a conductor is arranged inside the through hole. Here, the hole formed in the workpiece 20 is not limited to a through hole.

After the irradiating step SP18 is completed, processing returns to the table moving step SP11 when there is another processing portion, and laser processing is terminated when there is no other processing portion. Here, for forming a hole by the laser processing method as described above in a certain processing portion, for example, all of the beams of the laser light Lv may be transmitted through the aperture 344 as shown in FIG. 5 and radiated to the workpiece 20, and when moving to another processing portion, a part of the beams of the laser light Lv may be transmitted through the aperture 344 as shown in FIG. 6 and radiated to the workpiece 20 and the other part of the beams of the laser light Lv may be blocked by the frame member 344a. In this case, the laser processing processor 310 controls the first voltage application circuit 342d and the second voltage application circuit 342e to adjust the frequencies of the voltages applied to the first acousto-optic element 342a and the second acousto-optic element 342b so that the number of beams of the laser light Lv transmitted through the aperture 344 changes in accordance with the position of the workpiece 20.

### 3.3 Effect

As described above, the laser processing device 300 of the present embodiment is a laser processing device configured to form a hole at each irradiation position of the plurality of beams of the laser light Lv radiated to the workpiece 20, and includes the diffractive optical element 341 configured to divide the laser light Lb incident thereon into the plurality of beams of the laser light Lv and output the plurality of beams of the laser light Lv; the first acousto-optic element 342a on which the plurality of beams of the laser light Lv from the diffractive optical element 341 are incident, the first acousto-optic element 342a being configured to shift, in accordance with the frequency of the voltage applied thereto, the optical path of the plurality of beams of the laser light Lv output therefrom along the first direction perpendicular to the irradiation direction of the plurality of beams of the laser light Lv; the first voltage application circuit 342d configured to apply the voltage of the desired frequency to the first acousto-optic element 342a; the light concentrating optical system 343 configured to concentrate the plurality of beams of the laser light Lv output from the first acousto-optic element 342a and radiate the plurality of beams of the laser light Lv to the workpiece 20; and the laser processing processor 310 configured to control the first voltage application circuit 342d to adjust the frequency of the voltage applied to the first acousto-optic element 342a.

Further, the laser processing method of the present embodiment is a laser processing method for forming a hole at each irradiation position of the plurality of beams of the laser light Lv radiated to the workpiece 20, and includes the diffracting step SP13 for causing the laser light Lb to be incident on the diffractive optical element 341 and to be output as being divided into the plurality of beams of the laser light Lv, the first optical path shifting step SP14 for causing the plurality of beams of the laser light Lv from the diffractive optical element 341 to be incident on the first acousto-optic element 342a and applying the voltage of the desired frequency to the first acousto-optic element 342a to shift, in accordance with the frequency of the voltage applied thereto, the optical path of the plurality of beams of the laser light Lv output from the first acousto-optic element 342a along the first direction perpendicular to the irradiation direction of the plurality of beams of the laser light Lv, the light concentrating step SP16 for concentrating the plurality of beams of the laser light output from the first acousto-optic element 342a, and the irradiating step SP18 for irradiating the workpiece 20 with the concentrated plurality of beams of the laser light Lv.

According to the laser processing device 300 and the laser processing method, since the laser light Lb is divided into the plurality of beams of the laser light Lv by the diffractive optical element 341, blocked beams of the laser light are less than those when the laser light Lb is divided into the plurality of beams of the laser light Lv using the mask 335 as in the comparative example. Therefore, according to the laser processing device 300 of the present embodiment, energy efficiency can be improved. Further, the irradiation position of the laser light Lv can be adjusted by adjusting the frequency of the voltage applied to the first acousto-optic element 342a without moving the table 351. Therefore, the irradiation position of the laser light Lv can be adjusted in a short time.

Further, the laser light Lb of the present embodiment is pulse laser light. Therefore, the steeple value of the energy of the plurality of beams of the laser light Lv radiated to the workpiece 20 can be increased, and a hole can be efficiently formed. Here, the laser light Lb may be continuous light.

Further, the laser processing device 300 of the present embodiment further includes the second acousto-optic element 342b on which the plurality of beams of the laser light Lv from the first acousto-optic element 342a are incident and which shifts the optical path of the plurality of beams of the laser light Lv output therefrom along the second direction perpendicular to the irradiation direction of the plurality of beams of the laser light Lv and the first direction in accordance with the frequency of the voltage applied thereto, and the second voltage application circuit 342e which applies the voltage of the desired frequency to the second acousto-optic element 342b. Then, the laser processing processor 310 controls the second voltage application circuit 342e to adjust the frequency of the voltage applied to the second acousto-optic element 342b, and the plurality of beams of the laser light Lv output from the first acousto-optic element 342a are incident on the light concentrating optical system 343 via the second acousto-optic element 342b. Further, the laser processing method of the present embodiment further includes the second optical path shifting step SP15 for causing the plurality of beams of the laser light Lv from the first acousto-optic element 342a to be incident on the second acousto-optic element 342b and applying the voltage of the desired frequency to the second acousto-optic element 342b to shift, in accordance with the frequency of the voltage applied thereto, the optical path of the plurality of beams of the laser light Lv output from the second acousto-optic element 342b along the second direction perpendicular to the irradiation direction of the plurality of beams of the laser light Lv and the first direction, and in the light concentrating step SP16, the plurality of beams of the laser light Lv output from the first acousto-optic element 342a via the second acousto-optic element 342b are concentrated.

By including the second acousto-optic element 342b which shifts the optical path of the plurality of beams of the laser light Lv along the second direction as described above, the irradiation position on the workpiece 20 with the plurality of beams of the laser light Lv can be changed two-dimensionally including the first direction and the second direction. Here, in a case that the irradiation position on the workpiece 20 with the plurality of beams of the laser light Lv is changed not two-dimensionally but one-dimensionally, the laser processing device 300 does not have to include the second acousto-optic element 342b and the second voltage application circuit 342e, and the laser processing method does not have to include the second optical path shifting step SP15.

Further, in the laser processing device 300 of the present embodiment, the λ/2 wave plate 342c is arranged between the first acousto-optic element 342a and the second acousto-optic element 342b, and the laser light Lv from the first acousto-optic element 342a is incident on the second acousto-optic element 342b via the λ/2 wave plate 342c. Therefore, the polarization direction of linear polarization of the laser light Lv incident on the first acousto-optic element 342a with respect to the first direction and the polarization direction of the linear polarization of the laser light Lv incident on the second acousto-optic element 342b with respect to the second direction can be aligned. Therefore, the degree of shift in the optical path of the plurality of beams of the laser light Lv with respect to the frequency of the voltage applied to the first acousto-optic element 342a and the degree of shift in the optical path of the plurality of beams of the laser light Lv with respect to the frequency of the voltage applied to the second acousto-optic element 342b can be easily aligned, and the shift in the optical path of the laser light Lv in the first direction and the second direction can be easily controlled. Even in the case that the second acousto-optic element 342b is provided, the λ/2 wave plate 342c is not an essential configuration.

Further, the laser processing device 300 of the present embodiment further includes the aperture 344 through which the plurality of beams of the laser light Lv output from the light concentrating optical system 343 are transmitted as having a quadrangular shape formed of a pair of sides extending in the first direction and a pair of sides extending in the second direction. Here, the diffractive optical element 341 outputs the plurality of beams of the laser light Lv in a square lattice shape in which the plurality of beams of the laser light Lv are arranged in plural in the first direction and in plural in the second direction, and the laser processing processor 310 controls the first voltage application circuit 342d and the second voltage application circuit 342e to adjust the frequencies of the voltages applied to the first acousto-optic element 342a and the second acousto-optic element 342b so that, among the plurality of beams of the laser light Lv transmitted through the aperture 344, the number of the beams arranged in the first direction and the number of the beams arranged in the second direction become desired numbers, respectively. Further, the laser processing method of the present embodiment further includes the aperture transmitting step SP17 for causing the plurality of beams of the laser light Lv concentrated in the light concentrating step SP16 to be transmitted through the aperture 344 having a quadrangular shape formed of a pair of sides extending in the first direction and a pair of sides extending in the second direction. In the diffracting step SP13, the plurality of beams of the laser light Lv are output from the diffractive optical element 341 in a square lattice shape in which the beams are arranged in plural in the first direction and in plural in the second direction, and in the first optical path shifting step SP14 and the second optical path shifting step SP15, the frequencies of the voltages applied to the first acousto-optic element 342a and the second acousto-optic element 342b are adjusted so that, among the plurality of beams of the laser light Lv transmitted through the aperture 344, the number of the beams arranged in the first direction and the number of the beams arranged in the second direction become desired numbers, respectively.

According to the laser processing device 300 and the laser processing method, holes aligned in a matrix can be formed. Further, the number of beams of the laser light Lv transmitted through the aperture 344 in the first direction and the number thereof in the second direction can be adjusted even without moving the aperture 344, and the number of beams of the laser light Lv transmitted through the aperture 344 can be changed in a short time. Here, when all of the plurality of beams of the laser light Lv are always radiated to the workpiece 20, the aperture 344 may be omitted. In this case, for example, after a plurality of holes are formed by irradiating the workpiece 20 with the plurality of beams of the laser light Lv in a 5×5 square lattice shape, the optical path of the plurality of beams of the laser light Lv is shifted in the first direction, and a plurality of holes are formed again in a 5×5 square lattice shape adjacent to the plurality of formed holes, whereby 5×10 holes can be formed.

Here, the shape of the aperture 344 may not be a quadrangle. For example, the shape of the aperture 344 may be a triangle or a circle. When the shape of the aperture 344 is a triangle, it is preferable that the plurality of beams of the laser light Lv output from the diffractive optical element 341 are arranged in a triangular lattice shape from the viewpoint of easily controlling the number of beams of the laser light Lv transmitted through the aperture 344. Even when the shape of the aperture 344 is other than a quadrangle as described above, the laser processing processor 310 controls the first voltage application circuit 342d to adjust the frequency of the voltage applied to the first acousto-optic element 342a so that the number of beams of the laser light Lv transmitted through the aperture 344 becomes a desired number. In this case, the laser processing processor 310 may further control the second voltage application circuit 342e to adjust the frequency of the voltage applied to the second acousto-optic element 342b so that the number of beams of the laser light Lv transmitted through the aperture 344 becomes a desired number.

Further, the laser processing device 300 of the present embodiment includes the table 351 on which the workpiece 20 is placed and which is movable in the first direction and the second direction, and the laser processing processor 310 controls the first voltage application circuit 342d and the second voltage application circuit 342e to adjust the frequencies of the voltages applied to the first acousto-optic element 342a and the second acousto-optic element 342b so that the number of the beams of the laser light Lv transmitted through the aperture 344 changes in accordance with the position of the workpiece 20. Further, the laser processing method of the present embodiment further includes the table moving step SP11 for moving, in the first direction and the second direction, and in the first optical path shifting step SP14 and the second optical path shifting step SP15, the frequencies of the voltages applied to the first acousto-optic element 342a and the second acousto-optic element 342b are adjusted so that the number of the plurality of beams of the laser light Lv transmitted through the aperture 344 changes in accordance with the position of the workpiece 20.

In the comparative example, the number of beams of the laser light Lv radiated to the workpiece 20 cannot be changed unless the mask 335 is replaced. However, according to the laser processing device 300 and the laser processing method of the present embodiment, since the number of beams of the laser light Lv transmitted through the aperture 344 can be controlled without moving the position of the aperture 344, the number of beams of the laser light Lv radiated to the workpiece 20 can be changed in a short time.

### 4. Description of Laser Processing System and Laser Processing Method of Second Embodiment

Next, the laser processing system 10 and the laser processing method of a second embodiment will be described. Any component same as that described above is denoted by an identical reference sign, and duplicate description thereof is omitted unless specific description is needed.

### 4.1 Configuration

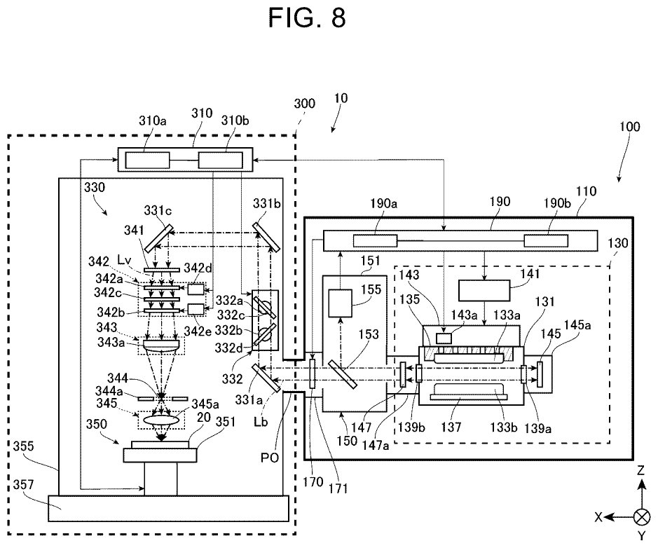

FIG. 8 is a schematic diagram showing a schematic configuration example of the laser processing device 300 of the present embodiment. The laser processing device 300 of the present embodiment is different from the laser processing device 300 of the first embodiment in that a transfer optical system 345 is arranged between the aperture 344 and the workpiece 20. In the example of FIG. 8, the transfer optical system 345 includes a transfer lens 345a. In the present embodiment, the focal plane of the light concentrating optical system 343 is located at the aperture 344. Further, the transfer optical system 345 is arranged such that the focal plane on the incident side is located at the aperture 344 and the focal plane on the output side is located substantially at a predetermined depth from the workpiece

### 4.2 Operation

Next, operation of the laser processing system 10 and the laser processing method of the present embodiment will be described. In the present embodiment, the plurality of beams of the laser light Lv output from the light concentrating optical system 343 and transmitted through the aperture 344 are concentrated on the incident surface of the transfer lens 345a of the transfer optical system 345 and transmitted through the transfer lens 345a. The plurality of beams of the laser light Lv transmitted through the transfer lens 345a are radiated to the workpiece 20 in a transferred state. Therefore, it can be understood that the laser processing method of the present embodiment includes a transferring step between the aperture transmitting step SP17 and the irradiating step SP18 in the flowchart shown in FIG. 7.

### 4.3 Effect

In the laser processing device 300 and the laser processing method of the present embodiment, the transfer optical system 345 arranged between the aperture 344 and the workpiece 20 is provided, and a plurality of beams of the laser light Lv output from the light concentrating optical system 343 are radiated to the workpiece 20 via the transfer optical system 345. Therefore, it is possible to secure a distance between the workpiece 20 and the aperture 344, and it is possible to suppress the occurrence of a problem due to the aperture 344 being too close to the workpiece 20.

### 5. Description of Laser Processing System and Laser Processing Method of Third Embodiment

Next, the laser processing system 10 and the laser processing method of a third embodiment will be described. Any component same as that described above is denoted by an identical reference sign, and duplicate description thereof is omitted unless specific description is needed. The schematic configuration of the laser processing system 10 of the present embodiment is similar to that of the laser processing system 10 of the first or second embodiment.

### 5.1 Operation

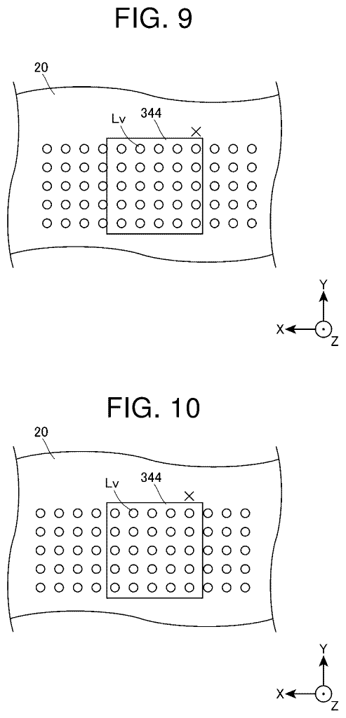

FIG. 9 is a diagram showing a state of laser processing in the present embodiment. In FIG. 9, although the aperture 344 is shown, the frame member 344a is omitted. In FIG. 9, all of the beams of the laser light Lv are transmitted through the aperture 344 in a similar manner as in the laser processing shown in FIG. 5. However, the position of each beam of the laser light Lv with respect to the aperture 344 is shifted in the −X direction from the position of each beam of the laser light Lv with respect to the aperture 344 shown in FIG. 5.

FIG. 10 is a diagram showing a state of laser processing after the state shown in FIG. 9. For ease of understanding, in FIGS. 9 and 10, a cross mark indicating a specific position of the workpiece 20 is shown. As shown in FIGS. 9 and 10, the cross mark is shifted in the X direction in the state shown in FIG. 10 from the state shown in FIG. 9. That is, in the present embodiment, the laser processing processor 310 controls the stage 350 to move the table 351 even during the period in which each beam of the laser light Lv is transmitted through the aperture 344 and radiated to the workpiece 20. In the present example, the table 351 is moved in the X direction which is the first direction.

Further, in FIG. 10, the transmission position of the aperture 344 of each beam of the laser light Lv is shifted in the X direction from the state of the laser processing shown in FIG. 9. This shift is the same as the shift of the cross mark in FIGS. 9 and 10, and the relative positional relationship between the cross mark and the irradiation position of each beam of the laser light Lv shown in FIG. 9 is the same as the relative positional relationship shown in FIG. 10. That is, in the present embodiment, the irradiation positions of the plurality of beams of the laser light Lv are moved so that the irradiation positions of the plurality of beams of the laser light Lv on the workpiece 20 do not change with the movement of the workpiece 20. In order to move the irradiation positions of the plurality of beams of the laser light Lv in this manner, the laser processing processor 310 controls the first voltage application circuit 342d during the movement of the table 351 to change the frequency of the voltage applied to the first acousto-optic element 342a. Due to the change in the frequency, the optical path of the plurality of beams of the laser light Lv output from the first acousto-optic element 342a shifts in the first direction by the amount of change in the frequency. For such operation, in the present embodiment, the table moving step SP11 is performed during the laser light outputting step SP12 to the irradiating step SP18 in the flowchart shown in FIG. 7.

Here, as shown in FIGS. 9 and 10, the processing portion extends in a matrix, and may exceed the range of the plurality of beams of the laser light Lv transmitted through the aperture 344 at once. In this case, just before the beam of the laser light Lv on the most X direction side is unable to be transmitted through the aperture 344, the laser processing processor 310 controls the first voltage application circuit 342d to change the frequency of the voltage applied to the first acousto-optic element 342a, and moves the plurality of beams of the laser light Lv in the −X direction by one row of the laser light Lv. Therefore, the transmission position of the plurality of beams of the laser light Lv with respect to the aperture 344 are again in the state shown in FIG. 9. During this time, the workpiece 20 continues to move in the X direction.

Here, as described above, the laser light Lv is pulse laser light, and it is preferable that each irradiation position on the workpiece 20 is irradiated with the pulse laser light for a plurality of times from the viewpoint of efficiently processing the workpiece 20. Further, between a period in which the pulse laser light is output and a subsequent period in which the pulse laser light is output, it is preferable to move the plurality of beams of the laser light Lv in the −X direction by one row of the laser light Lv as described above.

### 5.2 Effect

In the laser processing device 300 of the present embodiment, the laser processing processor 310 controls the first voltage application circuit 342d, while moving the table 351 in the first direction, to change the frequency of the voltage applied from the first voltage application circuit 342d to the first acousto-optic element 342a in synchronization with the movement of the table 351 so that the irradiation position of each beam of the laser light Lv on the workpiece 20 does not change. Further, in the laser processing method of the present embodiment, in the first optical path shifting step SP14, while moving the table 351, the frequency of the voltage applied to the first acousto-optic element 342a is changed in synchronization with the movement of the table 351 so that the irradiation position of each beam of the laser light Lv on the workpiece 20 does not change.

According to the laser processing device 300 and the laser processing method, it is possible to form holes in a wide range without stopping the workpiece 20. For example, in the comparative example, in the case of forming holes in a wide range, when laser processing is performed after moving and stopping the table 351 and laser processing is performed at a portion different from the portion where laser processing has been performed, it is necessary to perform laser processing after moving and stopping the table 351 again. It takes time to repeat the movement and the stoppage of the table 351 as described above. However, according to the laser processing device 300 and the laser processing method of the present embodiment, as compared with the case of the comparative example, it is possible to reduce the number of times of stopping the table 351, and it is possible to shorten the laser processing time in the case of forming holes in a wide range.

In the present embodiment, the workpiece 20 is not moved in the second direction. Therefore, the laser processing device 300 of the present embodiment does not have to include the second acousto-optic element 342b and the second voltage application circuit 342e, and the laser processing method of the present embodiment does not have to include the second optical path shifting step SP15.

In the laser processing device 300 and the laser processing method of the present embodiment, the first voltage application circuit 342d is controlled to change the frequency of the voltage applied from the first voltage application circuit 342d to the first acousto-optic element 342a so that each irradiation position on the workpiece 20 is irradiated with the pulse laser light for a plurality of times. Therefore, the workpiece 20 can be processed more efficiently than when the workpiece 20 is irradiated with the pulse laser light only once. Here, it is more preferable that the plurality of beams of the laser light Lv are moved in the −X direction by one row of the laser light Lv, and the pulse laser light is radiated for a plurality of times until the plurality of beams of the laser light Lb are subsequently moved in the −X direction by one row of the laser light Lv.

Further, in the laser processing device 300 and the laser processing method of the present embodiment, the diffractive optical element 341 outputs the plurality of beams of the laser light Lv in a square lattice shape arranged in plural in the first direction and the second direction, respectively, and the frequency of the voltage applied from the first voltage application circuit 342d to the first acousto-optic element 342a is changed in synchronization with the movement of the table 351 so that the irradiation position of each beam of the laser light Lv on the workpiece 20 does not change. Therefore, compared to a case in which the aperture 344 is not included, it is possible to suppress unintended processing due to incidence of unnecessary light on the workpiece 20.

Here, the laser processing device 300 of the present embodiment does not have to include the aperture 344, and the laser processing method of the present embodiment does not have to include the aperture transmitting step SP17. In the case that the laser processing device 300 does not include the aperture 344, the laser processing processor 310 changes the frequency of the voltage applied to the first acousto-optic element 342a and moves the plurality of beams of the laser light Lv in the −X direction by one row of the laser light Lv when the workpiece 20 is moved by a certain distance.

Although the present invention has been described with reference to the embodiments, the present invention is not limited thereto. For example, the number of beams of the laser light Lv and the pattern are not limited to the above-described embodiments. Further, the laser light Lb incident on the laser processing device 300 is not limited to the laser light from the gas laser device 100, and may be, for example, laser light from a solid state laser device. Further, the workpiece 20 is not limited to a substrate to be the interposer 502, and may be another member.

The description above is intended to be illustrative and the present disclosure is not limited thereto. Therefore, it would be obvious to those skilled in the art that various modifications to the embodiment of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser processing device configured to form a hole at each irradiation position of a plurality of beams of laser light radiated to a workpiece, the laser processing device comprising:
a diffractive optical element configured to divide laser light incident thereon into the plurality of beams of laser light and output the plurality of beams of laser light;
a first acousto-optic element on which the plurality of beams of laser light from the diffractive optical element are incident, the first acousto-optic element being configured to shift, in accordance with a frequency of a voltage applied thereto, an optical path of the plurality of beams of laser light output therefrom along a first direction perpendicular to an irradiation direction of the plurality of beams of laser light;
a first voltage application circuit configured to apply a voltage of a desired frequency to the first acousto-optic element;
a light concentrating optical system configured to concentrate the plurality of beams of laser light output from the first acousto-optic element and radiate the plurality of beams of laser light to the workpiece; and
a processor configured to control the first voltage application circuit to adjust the frequency of the voltage applied to the first acousto-optic element.

2. The laser processing device according to claim 1,
wherein the laser light is pulse laser light.

3. The laser processing device according to claim 1, further comprising an aperture through which the plurality of beams of laser light output from the light concentrating optical system are transmitted,
wherein the processor controls the first voltage application circuit to adjust the frequency of the voltage applied to the first acousto-optic element so that a number of the beams of laser light transmitted through the aperture becomes a desired number.

4. The laser processing device according to claim 3, further comprising a transfer optical system arranged between the aperture and the workpiece,
wherein the plurality of beams of laser light output from the light concentrating optical system is radiated to the workpiece via the transfer optical system.

5. The laser processing device according to claim 1, further comprising:
a second acousto-optic element on which the plurality of beams of laser light from the first acousto-optic element are incident, the second acousto-optic element being configured to shift, in accordance with a frequency of a voltage applied thereto, an optical path of the plurality of beams of laser light output therefrom along a second direction perpendicular to the irradiation direction of the plurality of beams of laser light and the first direction; and
a second voltage application circuit configured to apply a voltage of a desired frequency to the second acousto-optic element,
wherein the processor controls the second voltage application circuit to adjust the frequency of the voltage applied to the second acousto-optic element, and
the plurality of beams of laser light output from the first acousto-optic element are incident on the light concentrating optical system via the second acousto-optic element.

6. The laser processing device according to claim 5,
wherein a λ/2 wave plate is arranged between the first acousto-optic element and the second acousto-optic element, and
the plurality of beams of laser light from the first acousto-optic element are incident on the second acousto-optic element via the λ/2 wave plate.

7. The laser processing device according to claim 5, further comprising an aperture through which the plurality of beams of laser light output from the light concentrating optical system are transmitted, the aperture having a quadrangular shape formed of a pair of sides extending in the first direction and a pair of sides extending in the second direction,
wherein the diffractive optical element outputs the plurality of beams of laser light in a square lattice shape in which the beams are arranged in plural in the first direction and in plural in the second direction, and
the processor controls the first voltage application circuit and the second voltage application circuit to adjust the frequencies of the voltages applied to the first acousto-optic element and the second acousto-optic element so that, among the plurality of beams of laser light transmitted through the aperture, a number of the beams arranged in the first direction and a number of the beams arranged in the second direction become desired numbers, respectively.

8. The laser processing device according to claim 7, further comprising a table on which the workpiece is placed, the table being movable in the first direction and the second direction,
wherein the processor controls the first voltage application circuit and the second voltage application circuit to adjust the frequencies of the voltages applied to the first acousto-optic element and the second acousto-optic element so that the number of beams of laser light transmitted through the aperture changes in accordance with a position of the workpiece.

9. The laser processing device according to claim 1, further comprising a table on which the workpiece is placed, the table being movable in the first direction,
wherein the processor controls the first voltage application circuit, while moving the table in the first direction, to change the frequency of the voltage applied from the first voltage application circuit to the first acousto-optic element in synchronization with the movement of the table so that the irradiation position of each beam of the laser light on the workpiece does not change.

10. The laser processing device according to claim 9,
wherein the laser light is pulse laser light, and
the processor controls the first voltage application circuit to change the frequency of the voltage applied from the first voltage application circuit to the first acousto-optic element so that each of the irradiation positions on the workpiece is irradiated with the pulse laser light for a plurality of times.

11. The laser processing device according to claim 9, further comprising an aperture through which the plurality of beams of laser light output from the light concentrating optical system are transmitted, the aperture having a quadrangular shape formed of a pair of sides extending in the first direction and a pair of sides extending in a second direction perpendicular to the irradiation direction of the plurality of beams of laser light and the first direction,
wherein the diffractive optical element outputs the plurality of beams of laser light in a square lattice shape in which the beams are arranged in plural in the first direction and in plural in the second direction, and
the processor controls the first voltage application circuit to change the frequency of the voltage applied from the first voltage application circuit to the first acousto-optic element in synchronization with the movement of the table so that the irradiation position of each beam of the laser light on the workpiece does not change in the aperture.

12. The laser processing device according to claim 1,
wherein the workpiece is made of an insulating inorganic material.

13. A laser processing method for forming a hole at each irradiation position of a plurality of beams of laser light radiated to a workpiece, the laser processing method comprising:
a diffracting step for causing laser light to be incident on a diffractive optical element and to be output as being divided into the plurality of beams of laser light;
a first optical path shifting step for causing the plurality of beams of laser light from the diffractive optical element to be incident on a first acousto-optic element and applying a voltage of a desired frequency to the first acousto-optic element to shift, in accordance with the frequency of the voltage applied thereto, an optical path of the plurality of beams of laser light output from the first acousto-optic element along a first direction perpendicular to an irradiation direction of the plurality of beams of laser light;
a light concentrating step for concentrating the plurality of beams of laser light output from the first acousto-optic element; and
an irradiating step for irradiating the workpiece with the concentrated plurality of beams of laser light.

14. The laser processing method according to claim 13,
further comprising a second optical path shifting step for causing the plurality of beams of laser light from the first acousto-optic element to be incident on a second acousto-optic element and applying a voltage of a desired frequency to the second acousto-optic element to shift, in accordance with the frequency of the voltage applied thereto, an optical path of the plurality of beams of laser light output from the second acousto-optic element along a second direction perpendicular to the irradiation direction of the plurality of beams of laser light and the first direction,
wherein, in the light concentrating step, the plurality of beams of laser light output from the first acousto-optic element via the second acousto-optic element are concentrated.

15. The laser processing method according to claim 14,
further comprising an aperture transmitting step for causing the plurality of beams of laser light concentrated in the light concentrating step to be transmitted through an aperture having a quadrangular shape formed of a pair of sides extending in the first direction and a pair of sides extending in the second direction,
wherein, in the diffracting step, the plurality of beams of laser light are output from the diffractive optical element in a square lattice shape in which the beams are arranged in plural in the first direction and in plural in the second direction, and
in the first optical path shifting step and the second optical path shifting step, the frequencies of the voltages applied to the first acousto-optic element and the second acousto-optic element are adjusted so that, among the plurality of beams of laser light transmitted through the aperture, a number of the beams arranged in the first direction and a number of the beams arranged in the second direction become desired numbers, respectively.

16. The laser processing method according to claim 15,
further comprising a table moving step for moving, in the first direction and the second direction, a table on which the workpiece is placed,
wherein, in the first optical path shifting step and the second optical path shifting step, the frequencies of the voltages applied to the first acousto-optic element and the second acousto-optic element are adjusted so that the number of beams of laser light transmitted through the aperture changes in accordance with a position of the workpiece.

17. The laser processing method according to claim 13,
further comprising a table moving step for moving, in the first direction, a table on which the workpiece is placed,
wherein, in the first optical path shifting step, while moving the table, the frequency of the voltage applied to the first acousto-optic element is changed in synchronization with the movement of the table so that the irradiation position of each of the beams of laser light on the workpiece does not change.

18. The laser processing method according to claim 17,
wherein the laser light is pulse laser light, and
in the first optical path shifting step, the frequency of the voltage applied to the first acousto-optic element is changed so that each of the irradiation positions on the workpiece is irradiated with the pulse laser light for a plurality of times.

19. The laser processing method according to claim 17,
further comprising an aperture transmitting step for causing the plurality of beams of laser light concentrated in the light concentrating step to be transmitted through an aperture having a quadrangular shape formed of a pair of sides extending in the first direction and a pair of sides extending in a second direction perpendicular to the irradiation direction of the plurality of beams of laser light and the first direction,
wherein, in the diffracting step, the plurality of beams of laser light are output from the diffractive optical element in a square lattice shape in which the beams are arranged in plural in the first direction and in plural in the second direction, and
in the first optical path shifting step, the frequency of the voltage applied to the first acousto-optic element is changed in synchronization with the movement of the table so that the irradiation position of each of the beams of laser light on the workpiece does not change in the aperture.

20. An electronic device manufacturing method, comprising:
a first coupling step for coupling an interposer and an integrated circuit chip to provide electrical connection therebetween; and
a second coupling step for coupling the interposer and a circuit substrate to provide electrical connection therebetween,
the interposer including an insulating substrate in which a plurality of through holes are formed and conductors arranged in the plurality of through holes,
the plurality of through holes being formed by a laser processing method for forming holes at irradiation positions of a plurality of beams of laser light radiated to the insulating substrate, and
the laser processing method comprising:
a diffracting step for causing laser light to be incident on a diffractive optical element and to be output as being divided into the plurality of beams of laser light;
a first optical path shifting step for causing the plurality of beams of laser light from the diffractive optical element to be incident on a first acousto-optic element and applying a voltage of a desired frequency to the first acousto-optic element to shift, in accordance with the frequency of the voltage applied thereto, an optical path of the plurality of beams of laser light output from the first acousto-optic element along a first direction perpendicular to an irradiation direction of the plurality of beams of laser light;
a light concentrating step for concentrating the plurality of beams of laser light output from the first acousto-optic element; and
an irradiating step for irradiating the substrate with the concentrated plurality of beams of laser light.
